(19) United States
(12) Patent Application Publication
(10) Pub. No.: US 2026/0071979 A1
(43) Pub. Date: Mar. 12, 2026

(54) METHOD OF FORMING SI/SIGE SUPERLATTICE STRUCTURES USING XRF MEASUREMENTS AND PROCESS CONTROL TECHNIQUES

(71) Applicant: Applied Materials, Inc., Santa Clara, CA (US)

(72) Inventors: Biao LIU, San Jose, CA (US); Cheng PAN, San Jose, CA (US); Man-Ping CAI, Saratoga, CA (US); Michael PHILLIPS, Santa Clara, CA (US); Mahendra PAKALA, Santa Clara, CA (US); Steven Hiloong WELCH, Santa Clara, CA (US)

(21) Appl. No.: 19/321,663

(22) Filed: Sep. 8, 2025

Related U.S. Application Data
(60) Provisional application No. 63/692,660, filed on Sep. 9, 2024.

(51) Int. Cl. G01N 23/223; G01B 15/02; H01L 21/02; H01L 21/66

(52) U.S. Cl. CPC G01N 23/223; G01B 15/02; H10P 14/3411; H10P 74/203; G01N 2223/6116

(57) ABSTRACT

Methods and systems for epitaxial deposition using X-ray fluorescence (XRF) measurements and process control techniques are provided. The method involves performing an epitaxial deposition process to deposit alternating layers of silicon (Si) and silicon germanium (SiGe) on a substrate. XRF measurements determine the thickness and composition of these layers, allowing for precise control over layer thickness and composition. The process helps maintain the targeted strain and prevents defects, improving device performance. The XRF measurements can be performed in-situ or in a transfer chamber, enabling real-time adjustments to the deposition parameters. The method is applicable to various semiconductor devices, including 3D DRAM and gate-all-around (GAA) transistor devices.

### CROSS REFERENCE TO RELATED APPLICATIONS

This application claims the benefit of U.S. Provisional Patent Application Ser. No. 63/692,660, filed Sep. 9, 2024, which is incorporated by reference herein in its entirety.

### TECHNICAL FIELD

The present disclosure generally relates to semiconductor devices and methods for manufacturing semiconductor devices. More particularly, the disclosure relates to monitoring for control of multi-tier epitaxial deposition during formation of superlattice structures.

### BACKGROUND

An inflection in dynamic random-access memory (DRAM) technology is expected with the transition from a two-dimensional (2D) to a three-dimensional (3D) architecture. The transition is needed to meet the ever-growing demand for DRAM density (Gb/mm²).

One stage in the semiconductor manufacturing process of these 3D devices is epitaxial deposition of a superlattice stack of alternating Si and SiGe layers. These alternating layers can typically exceed 100 pairs in height. Each layer must comply with specific thickness standards.

For foregoing reasons, there is a need for methods and systems that can monitor and control thickness of layers in a superlattice stack.

### SUMMARY

The present disclosure generally relates to semiconductor devices and methods for manufacturing semiconductor devices. More particularly, the disclosure relates to monitoring for control of epitaxial deposition during formation of superlattice structures.

In one aspect, a method for substrate processing is provided. The method includes performing an epitaxial deposition process to deposit one or more layers on a surface of a substrate supported by a substrate support in a processing volume of a processing chamber. The method further includes performing an X-ray fluorescence measurement process by exposing the one or more layers to an X-ray fluorescence process. The X-ray fluorescence process determines a thickness of at least one of the one or more layers, a composition of the one or more layers, or both the thickness and composition of the one or more layers.

Implementations may include one or more of the following. The epitaxial deposition process includes flowing one or more reactive gases into the processing volume. The one or more reactive gases include a silicon-containing precursor, a germanium-containing precursor, or a combination thereof. The one or more layers include more than two pairs of alternating layers of silicon (Si) and silicon germanium (SiGe), each layer having a thickness in a range from about 50 Å to about 100 Å. The X-ray fluorescence process is performed in-situ while the substrate is positioned in the processing volume. The method further includes transferring the substrate from the processing volume to a transfer volume of a transfer chamber and performing the X-ray fluorescence process in the transfer volume.

In another aspect, a method of forming a superlattice structure is provided. The method includes performing an epitaxial deposition process in a processing volume to deposit at least a portion of a superlattice structure on a substrate. The superlattice structure includes a plurality of silicon layers and a plurality of silicon germanium (SiGe) layers alternately arranged in a plurality of stacked pairs. The method further includes performing an X-ray fluorescence measurement process by exposing the superlattice structure to an X-ray fluorescence process, the X-ray fluorescence process determines a thickness of at least one SiGe layer of the plurality of SiGe layers, a composition of the at least one SiGe layer, or both the thickness and composition of the at least one SiGe layer.

Implementations may include one or more of the following. The X-ray fluorescence process includes delivering an X-ray beam from an X-ray source. The X-ray beam impinging on a surface of the at least one SiGe layer in one or more measurement spots causing X-ray fluorescence of the at least one SiGe layer. The X-ray fluorescence process further includes detecting the X-ray fluorescence with an X-ray detector to determine X-ray fluorescence measurements. The method further includes adjusting one or more parameters of the epitaxial deposition process based on the X-ray fluorescence measurements and performing the epitaxial deposition process using the one or more adjusted parameters. The method further includes mapping the substrate based on the thickness of the at least one SiGe layer to determine within-wafer uniformity. The method further includes selectively heating predetermined locations of the substrate based on the X-ray fluorescence measurements. The X-ray fluorescence process is performed in-situ while the substrate is positioned in the processing volume. The method further includes transferring the substrate from the processing volume to a transfer volume of a transfer chamber and performing the X-ray fluorescence process in the transfer volume. The epitaxial deposition process and the X-ray fluorescence measurement process are performed sequentially. The epitaxial deposition process and the X-ray fluorescence measurement process are performed simultaneously.

In yet another aspect, a substrate processing system is provided. The substrate processing system includes a processing system and an XRF measurement system. The processing chamber includes an upper window, a lower window, a substrate support disposed between the upper window and the lower window, and a processing volume defined between a front surface of the substrate support and the upper window. The XRF measurement system includes an X-ray source positioned to generate an X-ray beam that impinges on a surface of a substrate in a measurement spot and an X-ray detector disposed adjacent to the X-ray source and positioned to receive X-ray fluorescence of a material of the substrate.

Implementations may include one or more of the following. The XRF measurement system is positioned above the upper window and the substrate is positioned on the front surface of the substrate support. A transfer chamber is positioned adjacent the processing chamber. The transfer chamber defines a transfer volume and the XRF measurement system is positioned in the transfer volume. The substrate processing system further includes a controller. The controller includes a memory storing computer readable instructions and a processor coupled to the memory. The processor is configured by the computer readable instructions that when executed by the processor perform a plurality of operations. The plurality of operations includes performing an epitaxial deposition process to deposit one or more layers on a surface of a substrate supported by the substrate support. The plurality of operations further include performing an X-ray fluorescence measurement process by exposing the one or more layers to an X-ray fluorescence process that determines a thickness of at least one of the one or more layers, a composition of the one or more layers, or both the thickness and composition of the one or more layers. The one or more layers include more than two pairs of alternating layers of silicon (Si) and silicon germanium (SiGe), each layer having a thickness in a range from about 50 Å to about 100 Å.

In another aspect, a non-transitory computer readable medium has stored thereon instructions, which, when executed by a processor, causes the process to perform operations of the above apparatus and/or method.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 is a schematic top view of a multi-chamber processing system incorporating an X-ray Fluorescence (XRF) measurement system in accordance with one or more implementations of the present disclosure.

FIG. 2 is a cross-sectional view of a processing chamber incorporating an X-ray Fluorescence (XRF) measurement system in accordance with one or more implementations of the present disclosure.

FIG. 3 illustrates an exemplary flow chart of a method of manufacturing a semiconductor device structure in accordance with one or more implementations of the present disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure generally relates to semiconductor devices and methods for manufacturing semiconductor devices. More particularly, the disclosure relates to monitoring for control of epitaxial deposition during formation of superlattice structures.

Superlattice structures may be utilized in the fabrication of devices that form integrated circuits. These superlattice structures incorporate films, for example, silicon (Si) and silicon germanium (SiGe) films, which possess varying characteristics depending upon the particular application for which the film is being deposited. Si/SiGe superlattice structures with a specific number of periods and layer thickness are helpful for fabricating 3D DRAM devices, aiming for high memory cell density. The lattice mismatch between silicon and germanium introduces strain in the SiGe layer when grown on silicon substrates. As the thickness of the SiGe layer increases, the strain energy stored within the layer also increases. Exceeding a certain critical thickness leads to strain relaxation and the formation of defects like misfit dislocations, which can degrade device performance. Carefully controlling the SiGe layer thickness, ensuring the thickness remains below the critical thickness, is helpful for maintaining the targeted strain and preventing the formation of defects. In addition, varying the Ge composition of SiGe also allows for adjustment of the lattice strain. Further, in some applications, it is desirable to form a silicon germanium film having a higher strain (as compared to an underlying silicon substrate) to improve electron mobility through silicon. Such improved electron mobility increases the speed of the device structure.

In one or more embodiments, the SiGe layer-to-layer as well as within wafer uniformity in Si/SiGe superlattice for 3D DRAM is measured by XRF (X-ray Fluorescence) techniques, where a source X-ray radiates on the specimen and excites fluorescence X-rays from the specimen. The fluorescence X-rays are detected by a detector and used to analyze the material.

In one or more embodiments, an X-ray Fluorescence (XRF) measurement system is added to an epitaxial reactor. The X-ray Fluorescence (XRF) measurement system includes an X-ray source and an X-ray detector for fluorescence. The X-ray travels through the window of the reactor which is transparent to both the source and the fluorescence X-rays. The XRF can be used in cycles of epitaxial deposition followed by XRF to measure the thickness of the deposited layers.

In one or more other embodiments, the XRF measurement system is positioned in the transfer chamber of a multi-chamber processing platform. In the transfer chamber, no window is needed between the substrate and the X-ray source and the X-ray detector for fluorescence. The deposited film can be moved from the epitaxial reactor into the transfer chamber for measurements, and either returned to the epitaxial reactor to continue processing or removed from the system to continue downstream processing.

In one or more embodiments, XRF is used in-situ X-ray fluorescence, for example, in the epitaxial deposition chamber or a transfer chamber of a cluster tool to measure the germanium concentration in the SiGe/Si superlattice (e.g., 10-200 pairs). The Si/SiGe superlattice can be used in 3D-DRAM applications. By measuring the thickness of the SiGe layers of the superlattice, various characteristics of the deposited film such as film quality and/or composition (e.g., the germanium counts) can be determined. In one or more embodiments where a third element is deposited in the film, the X-ray from the third element can be used to calculate the composition or dopant concentration. For example, the carbon concentration in SiGe:C can be measured with carbon, germanium, and silicon X-rays. Based on the thickness data of the SiGe layers, the wafer can be mapped to determine the within-wafer uniformity. Based on the thickness measurements from XRF, the epitaxial deposition process can be adjusted by, for example, changing temperature or gas flow (pressure, dosage, etcetera) in a feedback control process. In another embodiment, a laser spot can be delivered to the surface of the wafer to change temperature locally on the wafer to adjust epitaxial growth based on the XRF measurements. The XRF measurements can be performed under vacuum or near-vacuum conditions, or not under vacuum conditions (e.g., atmospheric pressure).

In one or more embodiments, the SiGe layer-to-layer as well as within wafer uniformity in Si/SiGe superlattice for 3D DRAM is measured by XRF (X-ray Fluorescence) techniques, where a source X-ray beam irradiates the sample (e.g., a silicon-germanium layer) and dislodges electrons from the inner shell of the sample. To fill the vacant spots, outer-shell electrons cascade down to fill the inner shells, which leads to the emission of X-ray photons with energies unique to each element knows as fluorescence. The XRF detector collects the emitted X-ray photons. As the XRF detector measures the energies of the X-ray photons and counts them, a spectrum is generated. The spectrum shows the number of counts as a function of photon energy. The number of counts can then be used to determine characteristics of the sample such as thickness.

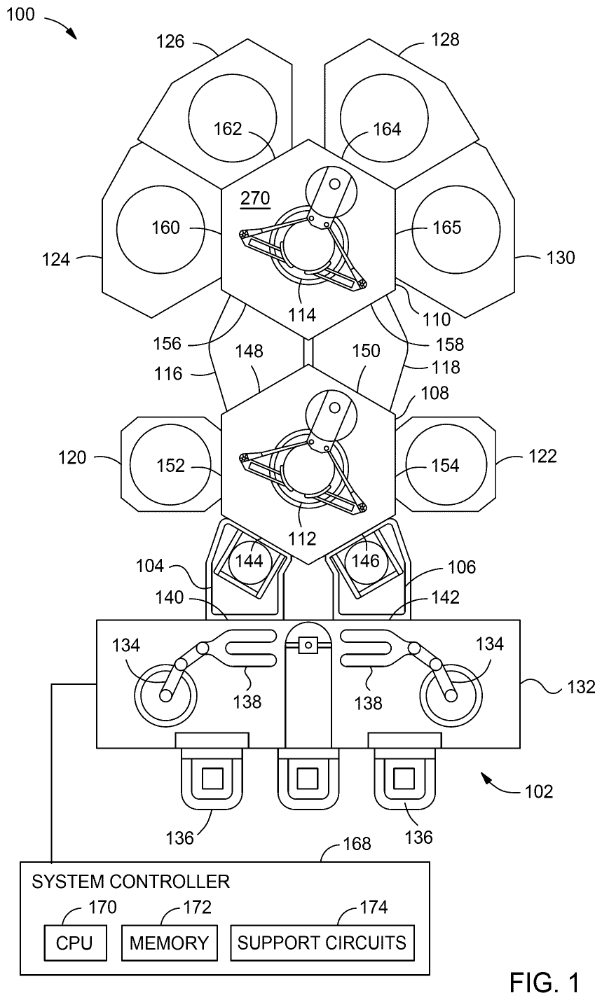

FIG. 1 is a schematic top view of a multi-chamber processing system 100 incorporating an X-ray Fluorescence (XRF) measurement system 270 in accordance with one or more implementations of the present disclosure. The multi-chamber processing system 100 generally includes a factory interface 102, load lock chambers 104, 106, transfer chambers 108, 110 with respective transfer robots 112, 114, holding chambers 116, 118, and processing chambers 120, 122, 124, 126, 128, 130. As detailed herein, substrates in the multi-chamber processing system 100 can be processed in and transferred between the various chambers without exposing the substrates to an ambient environment exterior to the multi-chamber processing system 100 (e.g., an atmospheric ambient environment such as may be present in a fab). For example, the substrates can be processed in and transferred between the various chambers maintained at a low pressure (e.g., less than or equal to about 300 Torr) or vacuum environment without breaking the low pressure or vacuum environment among various processes performed on the substrates in the multi-chamber processing system 100. Accordingly, the multi-chamber processing system 100 may provide an integrated solution for processing of substrates.

Examples of a processing system that may be suitably modified in accordance with the teachings provided herein include the Endura©, Producer© or Centura© integrated processing systems or other suitable processing systems commercially available from Applied Materials, Inc., located in Santa Clara, California. It is contemplated that other processing systems (including those from other manufacturers) may be adapted to benefit from aspects described herein.

In the illustrated example of FIG. 1, the factory interface 102 includes a docking station 132 and factory interface robots 134 to facilitate transfer of substrates. The docking station 132 is adapted to accept one or more front opening unified pods (FOUPs) 136. In one or more examples, each factory interface robot 134 generally includes a blade 138 disposed on one end of the respective factory interface robot 134 adapted to transfer the substrates from the factory interface 102 to the load lock chambers 104, 106.

The load lock chambers 104, 106 have respective ports 140, 142 coupled to the factory interface 102 and respective ports 144, 146 coupled to the transfer chamber 108. The transfer chamber 108 further has respective ports 148, 150 coupled to the holding chambers 116, 118 and respective ports 152, 154 coupled to processing chambers 120, 122. Similarly, the transfer chamber 110 has respective ports 156, 158 coupled to the holding chambers 116, 118 and respective ports 160, 162, 164, 165 coupled to processing chambers 124, 126, 128, 130. The ports 144, 146, 148, 150, 152, 154, 156, 158, 160, 162, 164, 165 can be, for example, slit valve openings with slit valves for passing substrates therethrough by the transfer robots 112, 114 and for providing a seal between respective chambers to prevent a gas from passing between the respective chambers. Generally, any port is open for transferring a substrate therethrough. Otherwise, the port can be closed.

The load lock chambers 104, 106, transfer chambers 108, 110, holding chambers 116, 118, and processing chambers 120, 122, 124, 126, 128, 130 may be fluidly coupled to a gas and pressure control system. The gas and pressure control system can include one or more gas pumps (e.g., turbo pumps, cryo-pumps, roughing pumps), gas sources, various valves, and conduits fluidly coupled to the various chambers. In operation, a factory interface robot 134 transfers a substrate from a FOUP 136 through a port 140 or 142 to a load lock chamber 104 or 106. The gas and pressure control system then pumps down the load lock chamber 104 or 106. The gas and pressure control system further maintains the transfer chambers 108, 110 and holding chambers 116, 118 with an interior low pressure or vacuum environment (which may include an inert gas). Hence, the pumping down of the load lock chamber 104 or 106 facilitates passing the substrate between, for example, the atmospheric environment of the factory interface 102 and the low pressure or vacuum environment of the transfer chamber 108.

In one or more embodiments, an XRF detection system, for example, the XRF measurement system 270 is positioned in the transfer chamber 110 as shown in FIG. 1.

With the substrate in the load lock chamber 104 or 106 that has been pumped down, the transfer robot 112 transfers the substrate from the load lock chamber 104 or 106 into the transfer chamber 108 through the port 144 or 146. The transfer robot 112 is then capable of transferring the substrate to and/or between any of the processing chambers 120, 122 through the respective ports 152, 154 for processing and the holding chambers 116, 118 through the respective ports 148, 150 for holding to await further transfer. Similarly, the transfer robot 114 is capable of accessing the substrate in the holding chamber 116 or 118 through the port 156 or 158 and is capable of transferring the substrate to and/or between any of the processing chambers 124, 126, 128, 130 through the respective ports 160, 162, 164, 165 for processing and the holding chambers 116, 118 through the respective ports 156, 158 for holding to await further transfer. The transfer and holding of the substrate 201 within and among the various chambers can be in the low pressure or vacuum environment provided by the gas and pressure control system.

The processing chambers 120, 122, 124, 126, 128, 130 can be any appropriate chamber for processing a substrate. In one or more examples, the processing chamber 120 can be capable of performing an etch process, the processing chamber 122 can be capable of performing a cleaning process, the processing chamber 124 can be capable of performing a selective removal process, and the processing chambers 126, 128, 130 can be capable of performing respective epitaxial growth processes. The processing chamber 120 may be a Selectra™ Etch chamber available from Applied Materials of Santa Clara, Calif. The processing chamber 122 may be a SiCoNi™ Pre-clean chamber available from Applied Materials of Santa Clara, Calif. The processing chamber 126, 128, or 130 may be a Centura™ Epi chamber available from Applied Materials of Santa Clara, Calif. The present disclosure contemplates that the deposition operations and the etching operations described herein can be conducted in the same chamber (such as in the same deposition chamber) or can be conducted in multiple chambers.

A system controller 168 is coupled to the multi-chamber processing system 100 for controlling the multi-chamber processing system 100 or components thereof. For example, the system controller 168 may control the operation of the multi-chamber processing system 100 using a direct control of the chambers 104, 106, 108, 110, 116, 118, 120, 122, 124, 126, 128, 130 of the multi-chamber processing system 100 or by controlling controllers associated with the chambers 104, 106, 108, 110, 116, 118, 120, 122, 124, 126, 128, 130. In operation, the system controller 168 enables data collection and feedback from the respective chambers to coordinate performance of the multi-chamber processing system 100.

The system controller 168 generally includes a central processing unit (CPU) 170, memory 172, and support circuits 174. The CPU 170 may be one of any form of a general-purpose processor that can be used in an industrial setting. The memory 172, or non-transitory computer-readable medium, is accessible by the CPU 170 and may be one or more of memory such as read only memory (ROM) (e.g., electrically erasable programmable read-only memory (EEPROM)), flash memory (e.g., flash drive), floppy disk, hard disk, random access memory (RAM) (e.g., non-volatile random access memory (NVRAM), dynamic random access memory (DRAM), static RAM (SRAM), and synchronous dynamic RAM (SDRAM (e.g., DDR1, DDR2, DDR3, DDR3L, LPDDR3, DDR4, LPDDR4, and the like)), or any other form of digital storage, local or remote. The support circuits 174 are coupled to the CPU 170 and may comprise cache, clock circuits, input/output subsystems, power supplies, and the like. The various methods disclosed herein (such as the method 300) may generally be implemented under the control of the CPU 170 by the CPU 170 executing computer instruction code stored in the memory 172 (or in memory of a particular processing chamber) as, for example, a software routine. When the computer instruction code is executed by the CPU 170, the CPU 170 controls the chambers to perform processes in accordance with the various methods.

The instructions stored in the memory 172 of the system controller 168 can include one or more machine learning/artificial intelligence algorithms that can be executed in addition to the operations described herein. As an example, a machine learning/artificial intelligence algorithm executed by the system controller 168 can generate, prioritize, accept, and/or reject signal profiles and/or data (such as metrology data and/or substrate map data) used in relation to the method 300. The machine learning/artificial intelligence algorithm can account for previous operational runs to monitor and update the signal profiles and/or data. The machine learning/artificial intelligence algorithm can optimize process parameter(s) of process recipes. The one or more machine learning/artificial intelligence algorithms can use, for example, a regression model (such as a linear regression model) or a clustering technique to estimate optimized parameters and/or optimized values for signal profiles and/or data. The algorithm(s) can be unsupervised or supervised. In one or more implementations, the system controller 168 automatically conducts the operations described herein without the use of one or more machine learning/artificial intelligence algorithms. In one or more implementations, the system controller 168 compares measurements to data in a look-up table and/or a library to optimize process parameters. The system controller 168 can store measurements as data in the look-up table and/or the library.

Other processing systems can be in other configurations. For example, more or fewer processing chambers may be coupled to a transfer apparatus. In the illustrated example, the transfer apparatus includes the transfer chambers 108, 110 and the holding chambers 116, 118. In one or more examples, more or fewer transfer chambers (e.g., one transfer chamber) and/or more or fewer holding chambers (e.g., no holding chambers) may be implemented as a transfer apparatus in a processing system.

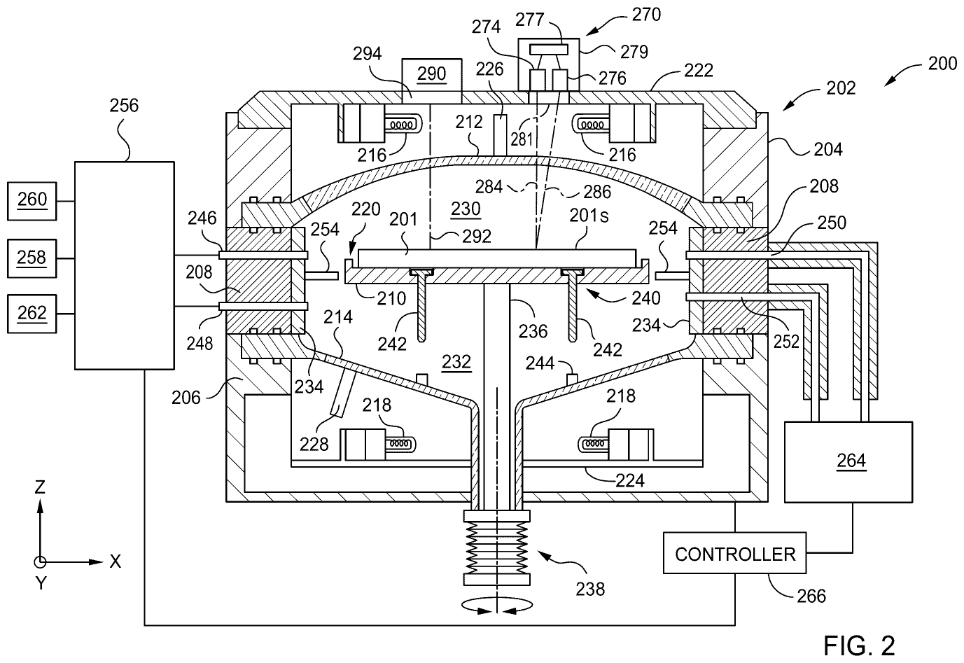

FIG. 2 is a schematic cross-sectional view of a system 200 for substrate processing incorporating an X-ray Fluorescence (XRF) measurement system in accordance with one or more implementations of the present disclosure. The system 200 includes a processing chamber 202. The processing chamber 202 can be one or more of the processing chambers 124, 126, 128, 130 of the multi-chamber processing system 100. In one or more embodiments, the processing chamber 202 is a deposition chamber. In one embodiment, which can be combined with other embodiments, the processing chamber 202 is an epitaxial deposition chamber. The processing chamber 202 is utilized to grow an epitaxial film on a substrate 201. The processing chamber 202 creates a crossflow of precursors across a surface 201s of the substrate 201 to deposit a film.

The processing chamber 202 includes an upper body 204, a lower body 206 disposed below the upper body 204, and a flow module 208 disposed between the upper body 204 and the lower body 206. The upper body 204, the flow module 208, and the lower body 206 form a chamber body. Disposed within the chamber body is a substrate support 210, an upper window 212 (such as an upper dome), a lower window 214 (such as a lower dome), upper heat sources 216, and lower heat sources 218.

The substrate support 210 is disposed between the upper window 212 and the lower window 214. The substrate support 210 includes a front surface 220 that faces the upper window 212 and supports the substrate 201. The substrate support 210 may be a disk-like substrate support as shown or may include a ring-like substrate support (not shown), which supports the substrate from the edge of the substrate, which exposes a backside of the substrate 201 to heat from the lower heat sources 216. The substrate support 210 may be formed from silicon carbide or graphite coated with silicon carbide to absorb radiant energy from the lower heat sources 216 and conduct the radiant energy to the substrate 201, thus heating the substrate 201. The substrate support 210 can be at a temperature greater than 200° C., for example, in a range from about 350° C. to about 1200° C.

The upper heat sources 216 are disposed between the upper window 212 and a lid 222. The lid 222 may be a reflector and optionally placed outside the upper window 212 to reflect infrared (IR) light that is radiating off the substrate 201 and redirect the energy back onto the substrate 201.

The lower heat sources 218 are disposed between the lower window 214 and a floor 224. The upper window 212 is an upper dome and is formed of an energy transmissive material, such as quartz. The lower window 214 is a lower dome and is formed of an energy transmissive material, such as quartz.

In the implementation shown in FIG. 2, the heat sources 216, 218 are lamps. Other heat sources are contemplated, such as resistive heaters, light emitting diodes (LEDs), and/or lasers. The heat sources 216, 218 may provide a total lamp power of between about 2 KW and about 150 KW. The heat sources 216, 218 may heat the substrate 201 to a temperature in a range from about 350 degrees Celsius and about 1150 degrees Celsius.

The processing chamber 202 may include one or more temperature sensors 226, 228, such as optical pyrometers, which measure temperatures within the processing chamber 202. The temperature sensor 226 (e.g., a top pyrometer) may be disposed on an upper side of the upper window 212. The temperature sensor 228 (e.g., a bottom pyrometer) may be disposed on a lower side of the lower window 214.

A processing volume (also referred to as an “upper volume”) 230 and a purge volume (also referred to as a “lower volume”) 232 are formed between the upper window 212 and the lower window 214. The processing volume 230 and the purge volume 232 are part of an internal volume defined at least partially by the upper window 212, the lower window 214, and one or more liners 234.

The internal volume has the substrate support 210 disposed therein. The purge volume 232 is on the opposite of the substrate support 210 from the front surface 220 and a substrate 201 disposed thereon. The substrate support 210 is attached to a shaft 236. The shaft 236, which is generally centered on the substrate support 210 and facilitates movement of the substrate support 210 in a vertical direction (Z direction) during substrate transfer, and in some instances, during processing of the substrate 201. The shaft 236 is connected to a motion assembly 238. The motion assembly 238 includes one or more actuators and/or adjustment devices that provide movement and/or adjustment for the shaft 236 and/or the substrate support 210 within the processing volume 230. The substrate support 210 can be rotated during processing by a rotary actuator to minimize the effect of thermal and process gas flow spatial anomalies within the processing chamber 202 and thus facilitates uniform processing of the substrate 201. In one or more embodiments, the substrate support 210 rotates in a range from about 5 RPM and about 100 RPM, for example, in a range from about 10 RPM to about 50 RPM.

The substrate support 210 may include lift pin holes 240 disposed therein. The lift pin holes 240 are sized to accommodate a lift pin 242 for lowering and/or lifting of the substrate 201 from the substrate support 210 before and/or after a deposition process is performed. The lift pins 242 may rest on lift pin stops 244 when the substrate support 210 is lowered from a process position to a transfer position. While in the transfer position, a robot, for example, the transfer robot 114, may then enter the processing chamber 202 to engage and remove the substrate 201 therefrom though the loading port. A new substrate may be loaded onto the lift pins 242 by the robot, and the substrate support 210 may then be actuated up to the processing position to place the substrate 201, with a device side of the substrate 201 facing up.

The flow module 208 includes a process inlet passage 246 in fluid communication with the processing volume 230, and a purge inlet passage 248 in fluid communication with the purge volume 232. The flow module 208 further includes a process outlet passage 250 in fluid communication with the processing volume 230, and a purge outlet passage 252 in fluid communication with the purge volume 232. The process inlet passage 246 and the purge inlet passage 248 are disposed on the opposite side of the flow module 208 from the process outlet passage 250 and the purge outlet passage 252. One or more flow guides 254 are disposed below the process inlet passage 246 and the process outlet passage 250. The one or more flow guides 254 are disposed above the purge inlet passage 248. In one or more embodiments, the one or more flow guides 254 include a pre-heat ring. One or more liners 234 are disposed on an inner surface of the flow module 208 and protect the flow module 208 from reactive gases used during deposition operations and/or cleaning operations. The process inlet passage 246 and the purge inlet passage 248 are each positioned to flow a gas parallel to the surface 201s of a substrate 201 disposed within the processing volume 230. The process inlet passage 246 and the purge inlet passage 248 are fluidly connected to a gas supply system 256 which coordinates the gases to be delivered to the processing chamber 202. One or more process gas sources 258, one or more cleaning gas sources 260, and one or more purge gas sources 262 are fluidly connected to the gas supply system 256. In one or more embodiments, the one or more process gas sources 258 include one or more reactive gas sources and one or more carrier gas sources.

The process outlet passage 250 and the purge outlet passage 252 are fluidly connected to an exhaust pump 264 (e.g., a vacuum pump).

One or more process gases supplied to the gas supply system 256 using the one or more process gas sources 258 can include one or more reactive gases (such as one or more of silicon (Si), phosphorus (P), and/or germanium (Ge)) and/or one or more carrier gases (such as one or more of nitrogen (N₂) and/or hydrogen (H₂)). One or more purge gases supplied using the one or more purge gas sources 262 can include one or more inert gases (such as one or more of hydrogen (H₂), argon (Ar), helium (He), and/or nitrogen (N₂)). One or more cleaning gases supplied using the one or more cleaning gas sources 260 can include one or more of hydrogen (H₂) and/or chlorine (Cl). In one embodiment, which can be combined with other embodiments, the one or more process gases include silicon phosphide (SiP) and/or phosphine (PH₃), and the one or more cleaning gases include hydrochloric acid (HCl). The present disclosure contemplates that the carrier gas(es), purge gas(es), and/or cleaning gas(es) are all candidates for recycling described herein.

As shown, the system 200 includes a controller 266 in communication with the processing chamber 202. The controller 266 is used to control processes and methods, such as the operations of the methods described herein. The controller 266 is in communication with the exhaust pump 264 and the gas supply system 256. The controller 266 controls the exhausted gas (exhausted from the processing chamber 202) using sensors disposed along the exhaust pump 264, and/or the gas supply system 256. By monitoring the purity content of the gas, the controller 266 can control the gas supply system 256 and determine and control where gas(es) flow in the system 200.

The controller 266 includes a central processing unit (CPU), a memory containing instructions, and support circuits for the CPU. The controller 266 controls various items directly, or via other computers and/or controllers. In one or more embodiments, the controller 266 is communicatively coupled with dedicated controllers, and the controller 266 functions as a central controller.

The controller 266 is of any form of a general-purpose computer processor that is used in an industrial setting for controlling various substrate processing chambers and equipment, and sub-processors thereon or therein. The memory, or non-transitory computer readable medium, is one or more of a readily available memory such as random access memory (RAM), dynamic random access memory (DRAM), static RAM (SRAM), and synchronous dynamic RAM (SDRAM (e.g., DDR1, DDR2, DDR3, DDR3L, LPDDR3, DDR4, LPDDR4, and the like)), read only memory (ROM), floppy disk, hard disk, flash drive, or any other form of digital storage, local or remote. The support circuits of the controller 266 are coupled to the CPU for supporting the CPU (a processor). The support circuits include cache, power supplies, clock circuits, input/output circuitry and subsystems, and the like. Operational parameters (the pressure of a recycled gas, the purity of a recycled gas, the chemical makeup of a recycled gas) and operations are stored in the memory as a software routine that is executed or invoked to turn the controller 266 into a specific purpose controller to control the operations of the various systems/chambers/recycling systems/modules described herein. The controller 266 is configured to conduct any of the operations described herein. The instructions stored on the memory, when executed, cause one or more operations of method 300 (described below) to be conducted.

The various operations described herein can be conducted automatically using the controller 266 or can be conducted automatically and/or manually with certain operations conducted by a user.

The controller 266 is configured to adjust output to controls of the system 200 based off sensor readings, a system model, and stored readings and calculations. The controller 266 includes embedded software and a compensation algorithm to calibrate measurements. The controller 266 can include one or more machine learning algorithms and/or artificial intelligence algorithms that estimate optimized parameters for deposition operation(s), purge operation(s), and/or cleaning operation(s). The one or more machine learning algorithms and/or artificial intelligence algorithms can use, for example, a regression model (such as a linear regression model) or a clustering technique to estimate optimized parameters. The algorithm can be unsupervised or supervised.

In one or more embodiments, the gas supply system 256 is responsible for providing all gases to the processing chamber 202 regardless of which gas source 258, 260, 262 supplies the gases. The gas supply system 256 is controlled by the controller 266.

The system 200 further includes the XRF measurement system 270, which enables accurate measurement of the thickness and/or composition of the various layers deposited on the substrate 201. The XRF measurement system 270 includes an X-ray source 274 and an X-ray detector 276. The XRF measurement system 270 can further include circuitry 277 for sending and receiving signals between the controller 266 and the X-ray source 274 and the X-ray detector 276. Each of the X-ray source 274 and the X-ray detector 276 are disposed above the substrate 201.

In one or more embodiments, the XRF measurement system 270 is disposed on or through the lid 222 to receive radiation from the device side or surface 201s of the substrate 201.

The X-ray source 274 can generate an X-ray beam 284 that impinges on the surface of the substrate 201 in a measurement spot. The X-ray source 274 can be a conventional X-ray emitter tube, for example, an anode of Rhodium (Rh), Gold (Au) or Tantalum (Ta). The X-ray source 274 can generate X-rays at a wavelength between 0.008 and 8 nm (energy between 0.12 and 120 keV). The X-ray beam 284 can impinge on the surface of the substrate 201 at an angle relative to normal, e.g., between 1° and 850.

In one or more embodiments, the X-ray beam 284 causes X-ray fluorescence (XRF) of the material of the substrate, which can be detected by the X-ray detector 276. In general, for a correctly selected wavelength, the intensity of fluorescence increases with the amount of material, for example, germanium. In one or more embodiments, the wavelength of the X-rays emitted by germanium is about 0.113 nm. X-ray fluorescence measurements RF can be conducted in an energy-dispersive mode or in a wavelength-dispersive mode. In the energy-dispersive mode, the X-rays emitted by the fluorescing material are directed onto a solid-state detector without using a grating to disperse the radiation (as is done in a wavelength-dispersive mode). The energy dispersive mode measures photon energies. The wavelength dispersive mode measures the energy of a well-defined, narrow wavelength range.

In one or more embodiments, the X-rays are reflected by the material of the substrate, and the absorption of the X-rays at a particular wavelength is detected.

In one or more embodiments the X-ray detector 276 is an X-ray spectrometer. A spectrometer is an optical instrument for measuring intensity of light over a portion of the electromagnetic spectrum. Typical output for an X-ray spectrometer is the intensity of the light as a function of energy (or wavelength or frequency).

The X-ray source 274 and X-ray detector 276 can be enclosed in a housing 279. A window 281 formed of a material, for example, glass or quartz, which is substantially transparent to X-rays, can be used to seal the housing 279 to prevent contaminants from damaging the components of the XRF measurement system 270. The window 281 is optically transparent to X-rays. In one or more embodiments, the window 281 can be disposed on or through the lid 222. In operation, the X-ray beam 284 is directed through the window 281, and X-rays 286 reflected or fluoresced by the substrate 201 travel back through the window 281 to the X-ray detector 276. The X-ray source 274, X-ray detector 276, and the window 281 constitute the probe for the XRF measurement system 270. In one or more embodiments, the window 281 includes a first window disposed adjacent to the X-ray source 274 and a second window disposed adjacent to the X-ray detector 276.

Due to the rotation of the substrate support 210, the XRF measurement system 270 can make measurements at a sampling frequency such that measurements are taken at locations in an arc that traverses the substrate 201 as the substrate rotates.

In one or more embodiments, the XRF measurement system 270 includes an actuator system to move the X-ray source 274 laterally in a plane parallel to the surface of the substrate 201. In one or more other embodiments, there is no actuator system, and the X-ray source 274 remains stationary (relative to the substrate support 210) while the substrate support 210 rotates to cause the spot measured by the XRF measurement system 270 to traverse a path on the substrate 201. In one or more embodiments, the XRF measurement system 270 includes a mechanism to adjust a vertical height of the X-ray source 274 and/or the X-ray detector 276 relative to the substrate support 210.

As noted above, the X-ray source 274 and the X-ray detector 276 can be connected to the controller 266, operable to control their operation and receive their signals. In operation, the controller 266 can receive, for example, a signal that carries information describing an intensity of the X-rays, for example, a spectrum of the X-rays, received by the X-ray detector 276.

In general, the wavelength of X-ray fluorescence is material specific. In addition, the intensity of the X-ray fluorescence at the particular wavelength is generally proportional to the amount of the material present. By selecting the wavelength at which the material, for example, germanium, fluoresces, the amount of germanium in the measurement spot on the substrate can be determined.

In general, the wavelength of X-ray absorption is also material specific. In addition, the absorption of the X-rays at the particular wavelength is generally proportional to the amount of the material present. By selecting the wavelength at which the material, for example, germanium, absorbs, the amount of metal in the measurement spot on the substrate can be determined.

In one or more embodiments, the system 200 further includes one or more spot heating source assemblies 290 for heating the substrate 201. The spot heating source assembly 290 is, for example, a laser system assembly. Power density of the laser system assembly may range from about 1 W/cm² to about 1000 W/cm², for example about 1 W/cm² to about 200 W/cm², for example about 200 W/cm² to about 1000 W/cm². In one or more embodiments, each spot heating source assembly 290 is coupled to and disposed on the lid 222. Each spot heating source assembly 290 directs radiant energy 292 through an opening 294 (which may have an optically transparent window therein) of the lid 222, through the upper window 212, and toward the substrate support 210. The radiant energy 292 from each spot heating source assembly 290 is directed towards the substrate support 210 to impinge upon one or more predetermined locations of the substrate 201 positioned on the substrate support 210. The radiant energy 292 from the spot heating source assembly 290 selectively heats predetermined locations of the substrate, resulting in more uniform substrate temperature (and thus more uniform deposition) during processing. The thermal energy provided by each spot heating source assembly 290 is directed to a location on the substrate 201 in response to thickness and/or composition measurements provided by the XRF measurement system 270 and one or more instructions from the controller 266.

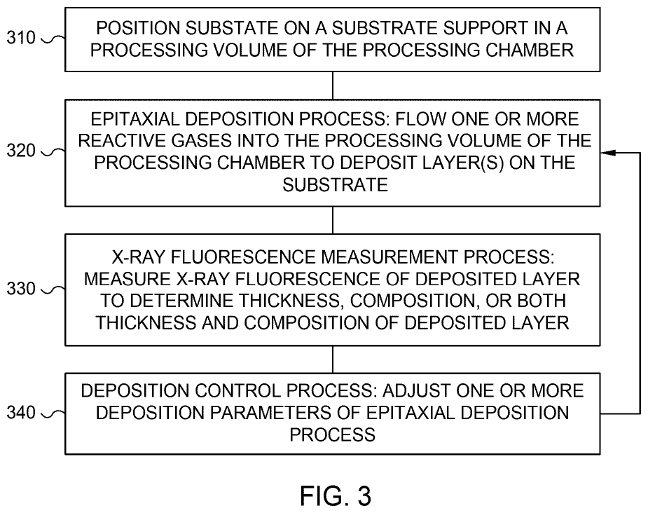

FIG. 3 illustrates an exemplary flow chart of a method 300 of manufacturing a semiconductor device structure in accordance with one or more implementations of the present disclosure. The method 300 can be used to control layer-to-layer thickness in a multi-tier epitaxial process using an XRF Detection system, for example, the XRF measurement system 270, positioned in a substrate processing system, such as the multi-chamber processing system 100 shown in FIG. 1 and/or the system 200 shown in FIG. 2. The method 300 may be part of a multi-operation fabrication process of a semiconductor device incorporating a superlattice structure, for example, a DRAM device or a gate-all-around (GAA) transistor device.

The method 300 begins at operation 310 during which a substrate, for example, the substrate 201, is positioned on a substrate support, for example, the substrate support 210, in the processing volume 230 of a processing chamber 202. It is contemplated that the substrate 201 may be a planar substrate or a patterned substrate. Patterned substrates are substrates that include electronic features formed into or onto a processing surface of the substrate. The substrate 201 may contain monocrystalline surfaces and/or one or more secondary surfaces that are non-monocrystalline, such as polycrystalline or amorphous surfaces. The secondary surface may be, for example, a patterned dielectric. Monocrystalline surfaces include the bare crystalline substrate or a deposited single crystal layer usually made from a material such as silicon, germanium, silicon germanium or silicon carbon. Polycrystalline or amorphous surfaces may include dielectric materials, such as oxides or nitrides, specifically silicon oxide or silicon nitride, as well as amorphous silicon surfaces. It is understood that the substrate 201 can include multiple layers, or include, for example, partially fabricated devices such as transistors, flash memory devices, and the like.

At operation 320, an epitaxial deposition process is performed to deposit layer(s) on the surface 201s of the substrate 201 supported on the front surface 220 of the substrate support 210 disposed in the processing volume 230 of the processing chamber 202. The epitaxial deposition process includes flowing one or more reactive gases from the one or more process gas sources 258 into the processing volume 230 of the processing chamber 202. The one or more reactive gases enter the processing volume 230 via the process inlet passage 246 above the one or more flow guides 254 and exit via the process outlet passage 250.

Layers that are deposited during operation 310 may be alternating layers of a first material, for example, silicon (Si), and a second material, for example, silicon germanium (SiGe). Each layer may have a thickness in a range from about 50 Å to about 1000 Å. The number of pairs of layers of the first material and the second material is more than 2, for example, in a range from 10 layers to 100 layers.

In one or more embodiments, the one or more reactive gases include a deposition gas and a carrier gas. The deposition gas includes a silicon or germanium-containing precursor and a dopant source. The dopant source may include a precursor phosphine (PH₃), phosphorus trichloride (PCl₃), triisobutylphosphine ([(CH₃)₃C]₃P), arsine (AsH₃), arsenic trichloride (AsCl₃), tertiarybutylarsine (AsC₄H₁₁), antimony trichloride (SbCl₃), or Sb(C₂H₅)₅, including n-type dopants such as phosphorus (P), arsenic (As), or antimony (Sb). The dopant source may include a precursor diborane (B₂H₆), or trimethylgallium Ga(CH₃)₃, including p-type dopants such as boron (B) or gallium (Ga). The carrier gas may include nitrogen (N₂), argon (Ar), helium (He), or hydrogen (H₂).

At operation 330, an X-ray fluorescence (XRF) monitoring process is performed. The XRF monitoring process includes measuring the X-ray fluorescence of a deposited layer to determine the thickness of the deposited layer. In one or more embodiments, the XRF monitoring process is performed in-situ in the same processing volume as the epitaxial deposition process of operation 320. For example, the XRF monitoring process is performed in the processing volume 230. The X-ray fluorescence (XRF) monitoring process of operation 330 may be performed prior to operation 320, simultaneously during operation 320, and/or sequentially after operation 320.

In one or more other embodiments, the XRF monitoring process is performed ex-situ to the processing volume in which the epitaxial deposition process of operation 320 is performed. For example, the XRF monitoring process is performed in the transfer chamber 110 after removal of the substrate 201 from the processing chamber 202 by the transfer robot 114. The XRF monitoring process can be performed by the XRF measurement system 270 positioned in the transfer chamber 110 while the substrate 201 is supported by the robot blade of the transfer robot 114.

Referring to FIG. 2, during operation 330, the X-ray source 274 emits the X-ray beam 284, the X-ray beam 284 travels through the upper window 212 and impinges on the surface of the substrate 201 in a measurement spot. The X-ray beam 284 can impinge on the surface of the substrate 201 at an angle relative to normal, e.g., between 1° and 85°. The X-ray beam 284 causes X-ray fluorescence (XRF) of the material of the substrate, the X-rays 286 reflected or fluoresced by the substrate 201 travel back through the window 281 to the X-ray detector 276.

In one or more embodiments, the XRF measurement system 270 is disposed on or through the lid 222 to receive radiation from the device side of the substrate 201.

The X-ray source 274 can generate an X-ray beam 284 that impinges the surface of the substrate 201 in a measurement spot. The X-ray source 274 can be a conventional X-ray emitter tube, for example, an anode of Rhodium (Rh), Gold (Au) or Tantalum (Ta). The X-ray source 274 can generate X-rays at a wavelength between 0.008 and 8 nm (energy between 0.12 and 120 keV).

In one or more embodiments, the X-ray beam 284 causes X-ray fluorescence (XRF) of the material of the substrate, which can be detected by the X-ray detector 276. In one or more embodiments, the X-rays are reflected by the material of the substrate, and the absorption of the X-rays at a particular wavelength is detected. In general, for a correctly selected wavelength, the intensity of fluorescence increases with the amount of material, for example, germanium. X-ray fluorescence measurements RF can be conducted in an energy-dispersive mode or in a wavelength-dispersive mode. In the energy-dispersive mode, the X-rays emitted by the fluorescing material are directed onto a solid-state detector without using a grating to disperse the radiation (as is done in a wavelength-dispersive mode). The energy dispersive mode measures photon energies. The wavelength dispersive mode measures the energy of a well-defined, narrow wavelength range.

In one or more embodiments, due to the rotation of the substrate support 210 during operation 330, the XRF measurement system 270 can make measurements at a sampling frequency such that measurements are taken at locations in an arc that traverses the substrate 201, as the substrate rotates.

As noted above, the X-ray source 274 and the X-ray detector 276 can be connected to the controller 266, operable to control their operation and receive their signals. In operation, the controller 266 can receive, for example, a signal that carries information describing an intensity of the X-rays, for example, a spectrum of the X-rays, received by the X-ray detector 276.

In general, the wavelength of X-ray fluorescence is material specific. In addition, the intensity of the X-ray fluorescence at the particular wavelength is generally proportional to the amount of the material present. By selecting the wavelength at which the material, for example, germanium, fluoresces, the amount or counts of germanium in the measurement spot on the substrate can be determined.

The germanium counts in counts per second (cps) measured by the XRF measurement system can be correlated with the number of silicon/SiGe tiers. The XRF Ge counts can be determined as follows:

$$XRF Ge counts ∝ {\int }_{i = 1}^{n} T i * C i * A i S * A i G e \qquad ( 1 )$$

In formula (I), T is thickness, C is concentration, and A is X-ray attenuation.

In general, the wavelength of X-ray absorption is also material specific. In addition, the absorption of the X-rays at the particular wavelength is generally proportional to the amount of the material present. By selecting the wavelength at which the material, for example, germanium, absorbs, the amount of germanium in the measurement spot on the substrate can be determined.

In one or more embodiments, the XRF monitoring process of operation 330 includes using the XRF measurement system 270 to make at least one measurement of X-ray intensity at the wavelength corresponding to the material of interest, for example, germanium. Measurements can be made at a set of first locations on the substrate 201. The measurements can be made after the underlying first material layer, for example, a silicon layer is deposited, but before the second material layer, for example, a silicon germanium layer, is deposited on the substrate 201.

Epitaxial deposition of the second material layer, for example, the silicon germanium layer progresses. At some point during or after the second material layer is formed, the XRF measurement system 270 is used to make at least one measurement. In one or more embodiments, a plurality of measurements is made at a set of second locations on the substrate 201. At least some of the second locations correspond to the first locations. Thus, the set of second locations can be or include a subset of the set of first locations.

In one or more embodiments, the plurality of measurements made with the XRF measurement system 270 trace out the same path on the substrate 201 as the set of first locations on the substrate 201 made with the XRF measurement system 270. It may be possible to correlate the positions of the second locations with the first locations simply by timing the measurements.

In one or more embodiments, the XRF measurement system 270 makes a larger number of measurements at the first locations on the substrate than the second locations on the substrate. For example, the XRF measurement system 270 can make measurements that are spaced uniformly across the substrate. The second locations of the measurements on the substrate by the XRF measurement system 270 can be determined, for example, by calculating positions of the measurements based on encoder signals. The controller 266 can determine which measurements are at corresponding locations.

The XRF measurement system 270 measures the X-ray intensity at the wavelength corresponding to the material of the silicon germanium layers. For at least one of the second locations that has a corresponding first locations, the signal intensity from the measurement before the silicon germanium layer was formed is subtracted from the signal intensity from the measurement after the silicon germanium layer was formed, which leaves a difference value that should scale with the thickness of the silicon germanium layers in the location. Optionally, the difference value can be converted to a thickness value, for example, by reference to a look-up-table or a discrete function, e.g., a linear function.

In one or more embodiments, the XRF measurement system 270 is used to make multiple measurements at the first locations distributed uniformly across the substrate, and an average value is calculated from those measurements. Then, during in-situ monitoring with the second X-ray monitoring system, the measurements at the second locations made during a sweep are averaged together. The average value from the measurements at the second locations can be compared to the average value from the measurements at the first locations. The difference which should scale with the average thickness of the silicon germanium layers across the substrate.

At operation 340 a deposition control process is performed. The deposition control process includes adjusting one or more epitaxial deposition parameters, for example, changing a deposition time, changing a deposition pressure, changing the substrate temperature in various locations, or changing the gas flow of one or more precursors, can be calculated based on the value output from the XRF monitoring process—either difference value or thickness value—and a target thickness for the silicon germanium layers.

The substrate may then be subjected to an additional epitaxial deposition process using the calculated deposition parameter from operation 340. Because the deposition parameter is based on the thickness of the silicon germanium layer(s), within-wafer and/or wafer-to-wafer uniformity of the thickness of the silicon germanium layer(s), and thus the overall quality of the superlattice structure and resulting DRAM structure, can be improved. Operations 320, 330, and 340 may be repeated in a cyclic process.

In one or more embodiments, which can be in alternative or in addition to the method above, the substrate is monitored in-situ, while the epitaxial deposition process of operation 320 is being performed, using the XRF measurement system 270. Positions on the substrate of measurements by the in-situ XRF measurement system 270 can calculated, for example, based on encoder signals from the motors driving the rotation of the substrate support 210. The signal intensity from a measurement at the location before the silicon germanium layer(s) was formed is subtracted from the signal intensity from the in-situ measurement at the location to generate a difference value which should be proportional to the thickness of the silicon germanium layer(s) in the location. The epitaxial deposition process of operation 320 can thus be controlled using the values measured in-situ.

In one or more embodiments, which can be in alternative or in addition to either of the methods above, the substrate is monitored using the XRF measurement system 270 after deposition of the silicon germanium layer(s). The method is similar to the first method, in that the signal intensity from the measurement at a first location before deposition of the silicon germanium layer(s) is subtracted from the signal intensity from a measurement at the location after the silicon germanium layer(s) has been deposited, which leaves a difference value that should be proportional to the thickness of the silicon germanium layers in the location. If the value indicates that the silicon germanium layer(s) is too thin, additional epitaxial deposition can be performed. Alternatively, or in addition, the values can be used in a feedback algorithm to adjust a deposition parameter for a subsequent substrate during the epitaxial deposition process.

In one or more embodiments, a laser spot can be delivered to a surface of the substrate to change temperature locally on the substrate to adjust epitaxial growth based on the XRF measurements. For example, in response to the values generated from the XRF monitoring process, the one or more spot heating source assemblies 290 can spot heat various locations on the substrate 201 to adjust epitaxial growth.

The germanium counts in counts per second (cps) measured by the XRF measurement system were correlated with the number of tiers. It was demonstrated that XRF has good linearity to the nominal SiGe thickness and high measurement repeatability (1σ<spec) on a single spot. Further, SiGe with-in-wafer thickness uniformity of 0.5% (vs spec (0.4%) was demonstrated with XRF.

The previously described embodiments of the present disclosure have many advantages. Enhanced Control and Precision: The use of X-ray fluorescence (XRF) measurements allows for precise control over the thickness and composition of the layers in the superlattice structure. The precision helps maintain the targeted strain and prevents defects such as misfit dislocations, which can degrade device performance. Improved Device Performance: By carefully controlling the SiGe layer thickness and ensuring it remains below the critical thickness, the use of XRF measurements helps maintain the targeted strain in the layers. The control improves electron mobility through silicon, which in turn increases the speed of the device structure. In-situ Monitoring: The XRF measurement system can be integrated into the epitaxial reactor, allowing for in-situ monitoring of the deposition process. The integration enables real-time adjustments to the deposition parameters, ensuring consistent layer quality and uniformity. Versatility: The use of XRF measurements can be applied to various semiconductor devices, including 3D DRAM and gate-all-around (GAA) transistor devices. The ability to adjust the Ge composition in SiGe layers allows for customization of the lattice strain to suit different applications. Feedback Control: The XRF measurements provide data that can be used in a feedback control process to adjust the epitaxial deposition parameters. The feedback loop ensures that the deposition process remains within the targeted specifications, leading to higher quality and more reliable semiconductor devices. Localized Adjustments: The use of XRF measurements includes the capability to selectively heat predetermined locations on the substrate based on XRF measurements. The localized heating allows for fine-tuning of the epitaxial growth, further enhancing the uniformity and quality of the deposited layers. However, the present disclosure does not necessitate that all the advantageous features and the advantages need to be incorporated into every embodiment of the present disclosure.

In the Summary and in the Detailed Description, and the Claims, and in the accompanying drawings, reference is made to particular features (including method operations) of the present disclosure. It is to be understood that the disclosure in the specification includes all possible combinations of such particular features. For example, where a particular feature is disclosed in the context of a particular aspect, implementation, implementation, or example of the present disclosure, or a particular claim, that feature can also be used, to the extent possible in combination with and/or in the context of other particular aspects and embodiments of the present disclosure, and in the present disclosure generally.

Embodiments and all the functional operations described in the specification can be implemented in digital electronic circuitry, or in computer software, firmware, or hardware, including the structural means disclosed in the specification and structural equivalents thereof, or in combinations of them. Embodiments described herein can be implemented as one or more non-transitory computer program products, i.e., one or more computer programs tangibly embodied in a machine readable storage device, for execution by, or to control the operation of, data processing apparatus, e.g., a programmable processor, a computer, or multiple processors or computers.

The processes and logic flows described in the specification can be performed by one or more programmable processors executing one or more computer programs to perform functions by operating on input data and generating output. The processes and logic flows can also be performed by, and apparatus can also be implemented as, special purpose logic circuitry, e.g., an FPGA (field programmable gate array) or an ASIC (application specific integrated circuit).

The term “data processing apparatus” encompasses all apparatus, devices, and machines for processing data, including by way of example a programmable processor, a computer, or multiple processors or computers. The apparatus can include, in addition to hardware, code that creates an execution environment for the computer program in question, e.g., code that constitutes processor firmware, a protocol stack, a database management system, an operating system, or a combination of one or more of them. Processors suitable for the execution of a computer program include, by way of example, both general and special purpose microprocessors, and any one or more processors of any kind of digital computer.

Computer readable media suitable for storing computer program instructions and data include all forms of nonvolatile memory, media and memory devices, including by way of example semiconductor memory devices, e.g., EPROM, EEPROM, and flash memory devices; magnetic disks, e.g., internal hard disks or removable disks; magneto optical disks; and CD ROM and DVD-ROM disks. The processor and the memory can be supplemented by, or incorporated in, special purpose logic circuitry.

The term “comprises,” and grammatical equivalents thereof are used herein to mean that other components, ingredients, operations, are optionally present. For example, an article “comprising” (or “which comprises”) components A, B, and C can consist of (i.e., contain only) components A, B, and C, or can contain not only components A, B, and C but also one or more other components. In addition, whenever a composition, an element or a group of elements is preceded with the transitional phrase “comprising” or grammatical equivalents thereof, it is understood that it is contemplated that the same composition or group of elements may be preceded with transitional phrases “consisting essentially of,” “consisting of,” “selected from the group of consisting of,” or “is” preceding the recitation of the composition, element, or elements and vice versa.

Where reference is made herein to a method comprising two or more defined operations, the defined operations can be carried out in any order or simultaneously (except where the context excludes that possibility), and the method can include one or more other operations which are carried out before any of the defined operations, between two of the defined operations, or after all of the defined operations (except where the context excludes that possibility).

When introducing elements of the present disclosure or exemplary aspects or implementation(s) thereof, the articles “a,” “an,” “the” and “said” are intended to mean that there are one or more of the elements.

The terms “comprising,” “including” and “having” are intended to be inclusive and mean that there may be additional elements other than the listed elements.

While the foregoing is directed to embodiments of the present disclosure, other and further embodiments of the disclosure may be devised without departing from the basic scope thereof, and the scope thereof is determined by the claims that follow.

What is claimed is:

1. A method for substrate processing, comprising:
performing an epitaxial deposition process to deposit one or more layers on a surface of a substrate supported by a substrate support in a processing volume of a processing chamber; and
performing an X-ray fluorescence measurement process by exposing the one or more layers to an X-ray fluorescence process that determines a thickness of at least one of the one or more layers, a composition of the one or more layers, or both the thickness and composition of the one or more layers.

2. The method of claim 1, wherein the epitaxial deposition process comprises flowing one or more reactive gases into the processing volume.

3. The method of claim 2, wherein the one or more reactive gases comprise a silicon-containing precursor, a germanium-containing precursor, or a combination thereof.

4. The method of claim 3, wherein the one or more layers comprise more than two pairs of alternating layers of silicon (Si) and silicon germanium (SiGe), each layer having a thickness in a range from about 50 Å to about 100 Å.

5. The method of claim 1, wherein the X-ray fluorescence process is performed in-situ while the substrate is positioned in the processing volume.

6. The method of claim 1, further comprising:
transferring the substrate from the processing volume to a transfer volume of a transfer chamber and performing the X-ray fluorescence process in the transfer volume.

7. A method of forming a superlattice structure, comprising:
performing an epitaxial deposition process in a processing volume to deposit at least a portion of a superlattice structure on a substrate, the superlattice structure comprising a plurality of silicon layers and a plurality of silicon germanium (SiGe) layers alternately arranged in a plurality of stacked pairs; and
performing an X-ray fluorescence measurement process by exposing the superlattice structure to an X-ray fluorescence process that determines a thickness of at least one SiGe layer of the plurality of SiGe layers, a composition of the at least one SiGe layer, or both the thickness and composition of the at least one SiGe layer.

8. The method of claim 7, wherein the X-ray fluorescence process comprises:
delivering an X-ray beam from an X-ray source, the X-ray beam impinging on a surface of the at least one SiGe layer in one or more measurement spots causing X-ray fluorescence of the at least one SiGe layer; and
detecting the X-ray fluorescence with an X-ray detector to determine X-ray fluorescence measurements.

9. The method of claim 8, further comprising:
adjusting one or more parameters of the epitaxial deposition process based on the X-ray fluorescence measurements; and
performing the epitaxial deposition process using the one or more adjusted parameters.

10. The method of claim 8, further comprising:
mapping the substrate based on the thickness of the at least one SiGe layer to determine within-wafer uniformity.

11. The method of claim 8, further comprising:
selectively heating predetermined locations of the substrate based on the X-ray fluorescence measurements.

12. The method of claim 7, wherein the X-ray fluorescence process is performed in-situ while the substrate is positioned in the processing volume.

13. The method of claim 7, further comprising:
transferring the substrate from the processing volume to a transfer volume of a transfer chamber and performing the X-ray fluorescence process in the transfer volume.

14. The method of claim 7, wherein the epitaxial deposition process and the X-ray fluorescence measurement process are performed sequentially.

15. The method of claim 7, wherein the epitaxial deposition process and the X-ray fluorescence measurement process are performed simultaneously.

16. A substrate processing system, comprising:
a processing chamber, comprising:
an upper window;
a lower window;
a substrate support disposed between the upper window and the lower window; and
a processing volume defined between a front surface of the substrate support and the upper window; and
an X-ray fluorescent (XRF) measurement system, comprising:
an X-ray source positioned to generate an X-ray beam that impinges on a surface of a substrate in a measurement spot; and
an X-ray detector disposed adjacent to the X-ray source and positioned to receive X-ray fluorescence of a material of the substrate.

17. The substrate processing system of claim 16, wherein the XRF measurement system is positioned above the upper window and the substrate is positioned on the front surface of the substrate support.

18. The substrate processing system of claim 16, further comprising:
a transfer chamber positioned adjacent the processing chamber, wherein the transfer chamber defines a transfer volume and the XRF measurement system is positioned in the transfer volume.

19. The substrate processing system of claim 16, further comprising:
a controller, comprising:
a memory storing computer readable instructions; and
a processor coupled to the memory, the processor configured by the computer readable instructions that when executed by the processor perform a plurality of operations, the plurality of operations comprising:
performing an epitaxial deposition process to deposit one or more layers on a surface of a substrate supported by the substrate support; and
performing an X-ray fluorescence measurement process by exposing the one or more layers to an X-ray fluorescence process that determines a thickness of at least one of the one or more layers, a composition of the one or more layers, or both the thickness and composition of the one or more layers.

20. The substrate processing system of claim 19, wherein the one or more layers comprise more than two pairs of alternating layers of silicon (Si) and silicon germanium (SiGe), each layer having a thickness in a range from about 50 Å to about 100 Å.
